(19) United States
(12) Patent Application Publication
(10) Pub. No.: US 2026/0032871 A1
(43) Pub. Date: Jan. 29, 2026

(54) Methods, Devices, and Systems for Dissipating Heat for High-Speed Interconnect Transceivers in Data Centers

(71) Applicant: Super Micro Computer, Inc., San Jose, CA (US)

(72) Inventors: Lawrence Lam, San Jose, CA (US); Lee Chia, Taiwan (TW)

(21) Appl. No.: 18/787,833

(22) Filed: Jul. 29, 2024

(51) Int. Cl. H05K 7/20; H05K 7/14

(52) U.S. Cl. CPC H05K 7/20781; H05K 7/1488; H05K 7/20272

(57) ABSTRACT

This application is directed to heat dissipation for interconnect transceivers applied in a server system. A server rack includes a rack structure for supporting one or more rack servers and a switch box mechanically mounted on the rack structure. The switch box is configured to receive detachable optical interconnects, and includes a transceiver module and a cooling structure coupled to the transceiver module. The transceiver module is configured to convert incoming signals to outgoing signals and generate heat while converting the incoming signals. The cooling structure is configured to inject a coolant via an inlet and output the coolant via an outlet, thereby allowing the coolant to at least partially carry away the heat generated by the transceiver module. In some embodiments, the cooling structure includes a metallic plate, which comes into contact with the transceiver module via a contact surface for absorbing the heat generated by the transceiver module.

### TECHNICAL FIELD

This application relates generally to cooling technology in electronic systems including, but not limited to, methods, apparatuses, structures, devices, and systems for dissipating heat generated by high-speed interconnect conversion and switching circuits that are applied in server systems and have compact form factors.

### BACKGROUND

Interconnect transceivers in a server rack are part of the hardware used to enable high-speed data transfer between servers, switches, and other networking equipment. They typically look like small, modular devices that are inserted into ports on networking hardware. Such interconnect transceivers, when applied in the server rack, can encounter several issues, primarily related to heat dissipation, signal integrity, and physical wear. As these transceivers operate at high data rates, they generate significant heat, which can lead to thermal management challenges within the confined space of the server rack. Overheating can result in reduced performance or even hardware failure if not properly managed with adequate cooling solutions. Additionally, maintaining signal integrity at high speeds is crucial; any degradation due to electromagnetic interference (EMI), poor quality cables, or connectors can result in data transmission errors, leading to network instability and increased latency.

Another concern is the physical durability of transceivers and their connections. Frequent insertion and removal of transceivers for maintenance or upgrades can wear out connectors and ports, leading to poor connectivity or complete failure of the interconnect. Dust and debris accumulation in the server rack can also affect connections and transceiver performance. Moreover, ensuring compatibility between different types and brands of transceivers and networking equipment can be complex, requiring thorough testing and validation to prevent interoperability issues. These challenges necessitate careful planning, regular maintenance, and proper environmental controls to ensure reliable and efficient operation of high-speed server interconnects.

### SUMMARY

Various embodiments of this application are directed to methods, apparatuses, structures, devices, and systems for dissipating heat generated by high-speed interconnect transceivers having compact form factors. For example, the interconnect transceivers can operate at data rates up to 1.6 Terabits per second (Tb/s) or 3.2 Tb/s in data centers that implement artificial intelligence tasks, thereby generating a large amount of heat that needs to be dissipated efficiently and in a timely manner. In some implementations, optical engines of individual communication channels are decoupled from associated optical fibers and integrated in a transceiver module, which is included in a switch box that is mechanically mounted on a rack structure. A cooling structure is disposed in the switch box and coupled to the transceiver module. The transceiver module may include optical engines of a plurality of communication channels associated with a plurality of optical fibers (e.g., 32 or 64 fibers). A coolant is configured to flow through a body of the cooling structure to at least partially carry away the heat generated by the transceiver module. By these means, the transceiver module may provide a compact form factor compared with optical engines that are separately packaged with optical fibers or associated ports, while benefiting from efficient cooling effects enabled by the cooling structure.

In accordance with at least some embodiments disclosed herein is the realization that optical fibers integrated with transceiver ports limit a port density of a switch box and that heat sinks or cold plates, which dissipate the switch box as a whole, can be bulky and insufficient to dissipate heat generated by transceivers associated with the optical fibers. Particularly, when a data center implements artificial intelligence (AI) or high performance computing (HPC) tasks, data transfer rates of associated servers exceed 1.6 Tb/s and 3.2 Tb/s, thereby requiring efficient heat dissipation on the transceivers coupled to the optical fibers. In some implementations, the optical fibers is separated from associated optical engines and/or a switching application-specific integrated circuit (ASIC), allowing the optical fibers to be closely arranged to enhance a port density. The switching ASIC can be efficiently cooled with a cooling structure, thereby supporting a signal-to-noise ratio that enables a desirable data transfer rate (e.g., 1.6 Tb/s and 3.2 Tb/s).

In one aspect, some implementations include a server rack. The server rack includes a rack structure for supporting one or more rack servers and a switch box mechanically mounted on the rack structure. The switch box further includes (e.g., encloses) a transceiver module and a cooling structure coupled to the transceiver module. The switch box is configured to receive a plurality of detachable optical interconnects, and the transceiver module is configured to convert a plurality of incoming signals to a plurality of outgoing signals and generate heat while the plurality of incoming signals are converted. The cooling structure includes an inlet and an outlet, and is configured to inject a coolant via the inlet and output the coolant via the outlet, thereby allowing the coolant to at least partially carry away the heat generated by the transceiver module.

In some implementations, the cooling structure includes a metallic plate having a contact surface, and the metallic plate comes into contact with the transceiver module via the contact surface for absorbing the heat generated by the transceiver module. Further, in some implementations, the metallic plate includes a coolant channel sealed within the metallic plate, and each of the inlet and the outlet is coupled to a respective edge of the metallic plate and connected to a respective end of the coolant channel, the coolant channel extending substantially parallel to the contact surface from the inlet to the outlet.

In some implementations, the switch box further includes a plurality of ports configured to receive a plurality of detachable electrical interconnects, and each of the plurality of ports is configured to exchange electrical signals with a respective rack server mounted on the rack structure.

In some implementations, the switch box further includes a plurality of ports configured to receive a plurality of detachable electrical interconnects, and a first subset of the plurality of ports is coupled to a plurality of rack server on a set of one or more alternative server racks, each alternative server rack including at least one rack server electrically coupled to a respective port of the first subset of ports.

In another aspect, some implementations include a modulator device that further includes a transceiver module enclosed in a switch box and a cooling structure coupled to the transceiver module. The switch box is configured to receive a plurality of detachable optical interconnects, and the transceiver module is configured to convert a plurality of incoming signals to a plurality of outgoing signals and generate heat while the plurality of incoming signals are converted. The cooling structure includes an inlet and an outlet, and is configured to inject a coolant via the inlet and output the coolant via the outlet, thereby allowing the coolant to at least partially carry away the heat generated by the transceiver box.

In yet another aspect, a method is implemented for providing a server rack. The method includes providing a rack structure for supporting one or more rack servers and providing a switch box mechanically mounted on the rack structure. The switch box is configured to receive a plurality of detachable optical interconnects. Providing the switch box includes providing a transceiver module, which is configured to convert a plurality of incoming signals to a plurality of outgoing signals and generate heat while the plurality of incoming signals are converted. Providing the switch box further includes providing a cooling structure coupled to the transceiver module. The cooling structure includes an inlet and an outlet, and is configured to inject a coolant via the inlet and output the coolant via the outlet, thereby allowing the coolant to at least partially carry away the heat generated by the transceiver module.

In yet another aspect, a method is implemented at a server rack including a rack structure for supporting one or more rack servers, a switch box mechanically mounted on the rack structure. The method includes receiving, by the switch box, a plurality of detachable optical interconnects. The switch box includes a transceiver module and a coolant structure coupled to the transceiver module. The method further includes receiving, by the transceiver module, a plurality of incoming signals via; converting, by the transceiver module, the plurality of incoming signals to a plurality of outgoing signals; and generating heat by the transceiver module while the plurality of incoming signals are converted. The method further includes injecting a coolant via an inlet of the cooling structure and outputting the coolant via an outlet of the cooling structure, thereby allowing the coolant to at least partially carry away the heat generated by the transceiver module.

These illustrative embodiments and implementations are mentioned not to limit or define the disclosure, but to provide examples to aid understanding thereof. Additional embodiments are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1A is a front view of an example server rack that supports one or more servers, in accordance with some embodiments.

FIG. 1B is an example data center including a hierarchy of servers organized on a plurality of server racks, in accordance with some embodiments.

FIG. 2 is a block diagram of an example system module in a typical computer device, which may be applied as a server in FIG. 1, in accordance with some embodiments.

FIGS. 3A and 3B are two simplified front views of an example server rack including a switch box, in accordance with some embodiments.

FIG. 4 illustrates a perspective view of a main board of an example switch box and a zoom-in view of a transceiver module disposed on the main board, in accordance with some embodiments.

FIG. 5A is an expanded perspective view of an integrated module including a cooling structure and a transceiver module coupled to the cooling structure, in accordance with some embodiments.

FIG. 5B is a top see-through view of an example cooling structure coupled to the transceiver module shown in FIG. 5A, in accordance with some embodiments.

FIGS. 6A-6C are cross sectional views of example switch boxes, in accordance with some embodiments.

FIG. 7 is a block diagram of a transceiver module coupled between a fiber port and a server-side port of a switch box, in accordance with some embodiments.

FIG. 8 illustrates a server group including a plurality of servers, in accordance with some embodiments.

FIG. 9A is a rear view of an example server rack including a server cooling system, in accordance with some embodiments, and FIG. 9B is a front view of another example server rack including a server cooling system, in accordance with some embodiments.

FIG. 10 is a flow diagram of a method for providing a server rack, in accordance with some embodiments.

FIG. 11 is a flow diagram of a method implemented at a server rack for managing incoming data, in accordance with some embodiments.

Like reference numerals refer to corresponding parts throughout the several views of the drawings.

### DETAILED DESCRIPTION

Reference will now be made in detail to specific embodiments, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details.

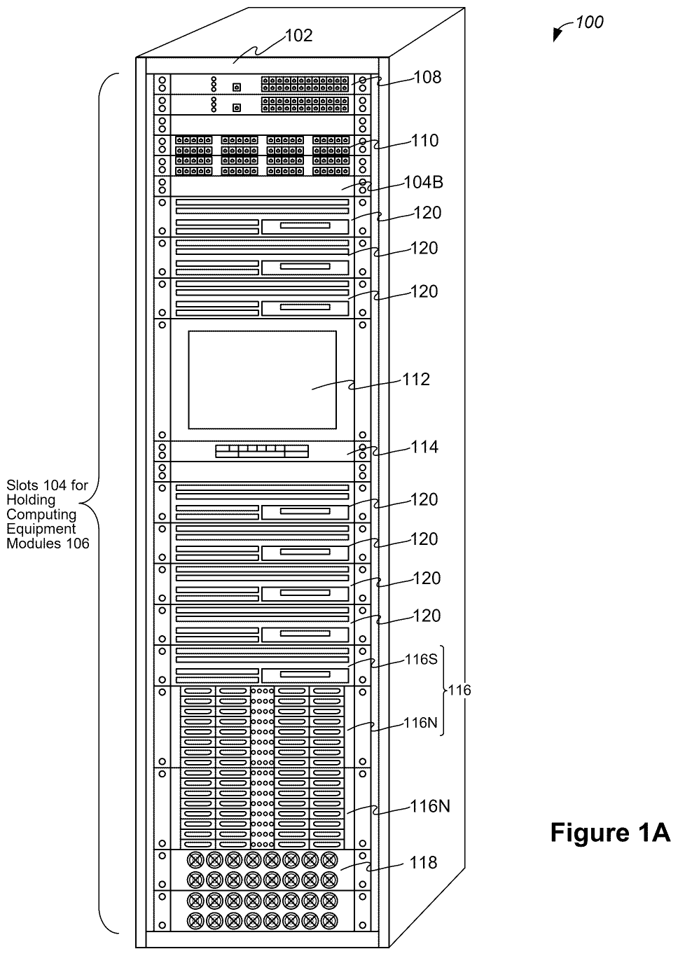

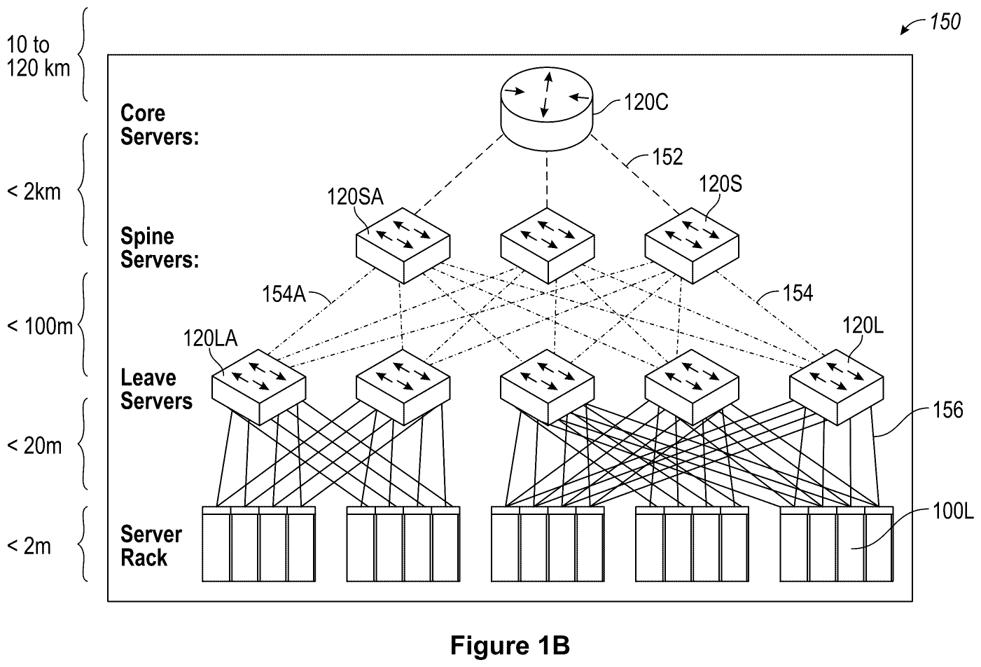

FIG. 1A is a front view of an example server rack 100 (also known as a rack mount, a rack cabinet, or simply a rack) that supports one or more servers 120, in accordance with some embodiments. The server rack 100 includes a frame 102 and a plurality of slots 104, and may be used in a data center, a server room, or a network closet for supporting, organizing, and managing a plurality of computing equipment modules 106 (e.g., servers 120, storage devices 116S and 116N, networking equipment, and other types of hardware). Each of the plurality of slots 104 of the server rack 100 is configured to receive and support a respective computing equipment module 106. In some embodiments, the plurality of slots 104 include at least one blank slot 104B that is not used to provide mechanical support to any equipment module 106 and can receive an equipment module 106 if needed. In some implementations, the server rack 100 has a predefined width of 19 or 23 inches, a height up to 84 inches or more, and a depth selected from 24, 32, 40, or 48 inches.

Examples of the computing equipment modules 106 supported by the plurality of slots 104 of the server rack 100 include, but are not limited to, a firewall module 108, a switch box 110, a server 120, a display device 112, a keyboard 114, a solid-state drive (SSD) 116S, a network-attached storage 116N, and an uninterruptible power supply (UPS) 118. Each computing equipment module 106 plays a respective role in maintaining a network and computing environment. In some embodiments, a firewall module 108 is a network security device that monitors and controls incoming and outgoing network traffic based on predetermined security rules, thereby establishing a barrier between a trusted internal network and untrusted external networks. The firewall module 108 may be placed near a network ingress point to protect the server rack 100 from unauthorized access, malware, and cyberattacks. In some embodiments, the firewall module 108 includes packet filtering, stateful inspection, VPN support, and intrusion prevention systems (IPS). In some embodiments, a switch box 110 is placed near the network ingress point jointly with the firewall module 108, and configured to receive incoming signals and forward the incoming signals (e.g., which may be converted to electrical signals) to different servers 120 mounted on the server rack 100. The switch box 110 is applied in the server rack 100 to minimize cable length and ensure efficient network traffic management. The switch box 110 may support different speeds (e.g., 800 gigabits per second (Gbps), 1.6 Tbs, 3.2 Tbs), have multiple ports (24, 48, etc.), and offer features like virtual local area network (VLAN) support, PoE (Power over Ethernet), and managed or unmanaged capabilities.

The plurality of computing equipment modules 106 of the server rack 100 may include a plurality of servers 120 each of which is configured to provides data, resources, services, or programs to other client devices over one or more wired or wireless communication networks. Each server 120 is mounted in a slot 104 of the server rack 100 and configured to provide one or more services (e.g., web hosting, database management, and application support). The servers 120, mounted on the server rack 100, may provide higher processing power, large memory capacity, redundant power supplies, and hot-swappable components for high availability and reliability compared with individual client devices. In some embodiments, the one or more rack servers 120 include a plurality of graphics processing units (GPU) configured to implement machine learning operations, e.g., in a data center 150 (FIG. 1B) associated with machine learning tasks.

The SSD 116S and the network-attached storage 116N are configured to provide storage space for the servers 120 installed in the server rack 100. The SSD uses flash memory to store data and shows high speed, low latency, durability, and lower power consumption, and diverse capacities and form factors compared to hard drive devices (HDDs). Conversely, the network-attached storage (NAS) 116N is a dedicated file storage device that provides data access to a network and allows a large number of different types of client devices to retrieve data from centralized disk capacity. In some embodiments, the network-attached storage 116N may have a high capacity, redundant array of independent disks (RAID), support for a plurality of file-sharing protocols (NFS, SMB/CIFS, FTP), user management, and backup features. In some embodiments, the SSDs 116S are storage drives for speed, and for example, used within the servers 120 disposed on the same server rack 100, while the NAS 116N is configured for file sharing, data backup, and remote access.

In some implementations, the UPS 118 is applied to provide emergency power to other computing equipment modules 106 in case of a power outage, allowing them to remain operational long enough to safely shut down or switch to an alternative power source. In an example, the UPS 118 is mounted in the server rack 100 or placed on a bottom slot to support the weight, providing backup power to other computing equipment modules 106. The UPS 118 provides one or more of battery backup, surge protection, voltage regulation, real-time monitoring, management software, and/or varying runtimes based on capacity and load.

The server rack 100 further includes a plurality of mechanical structures configured to provide mechanical support, or facilitate access, to the plurality of computing equipment modules 106. The plurality of mechanical structures include one or more of: an open frame rack (e.g., having no door or side panel), mounting rails, cable management features (e.g., arms, hooks, and trays), power strips, shelves, drawers, and blanking panels. In some embodiments, the plurality of mechanical structures also includes a rack enclosure (e.g. cabinet), lockable doors, and side panels to protect the computing equipment modules 106 from unauthorized access. In an example, the server rack 100 includes, or is coupled to, a plurality of panels configured to convert the server rack 100 to a server cabinet. In some embodiments, the server rack 100 further includes a cooling system or a ventilation system to facilitate heat dissipation. Using a server rack 100 helps optimize space, improve cooling efficiency, simplify maintenance, and enhance the overall organization and management of information technology (IT) infrastructure.

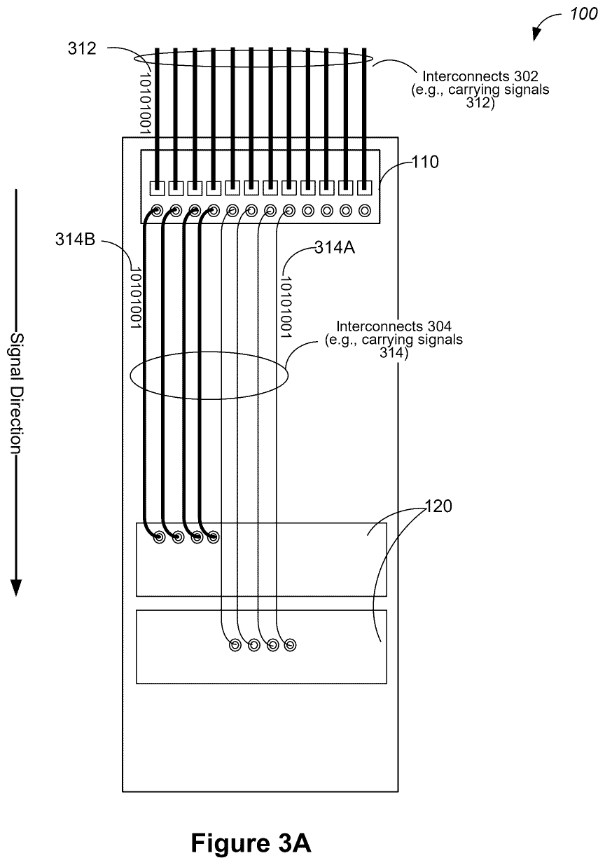

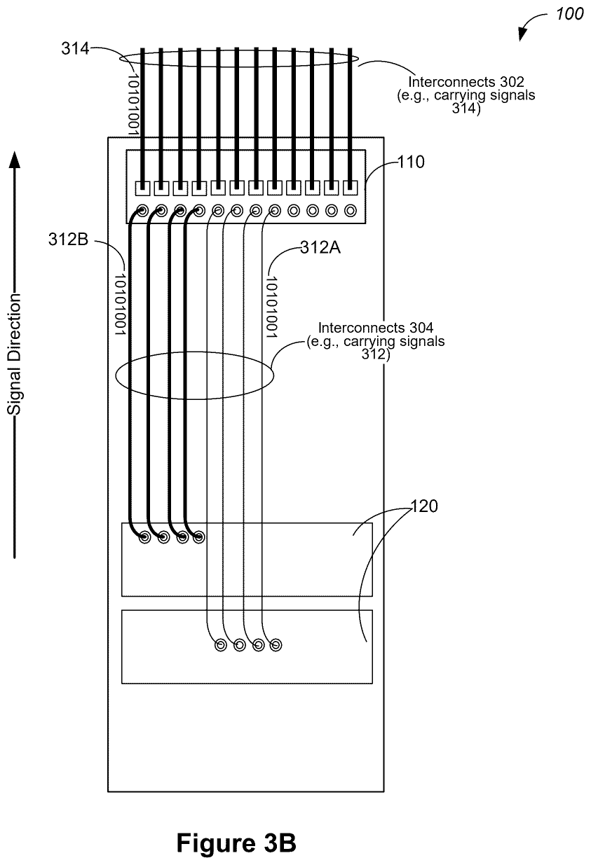

Some implementations of the server rack 100 include a rack structure (e.g., including a frame 102 and a plurality of slots 104) for supporting one or more rack servers 120. The switch box 110 includes a transceiver module (e.g., 410 in FIG. 3B) and an associated cooling structure (e.g., 510 in FIG. 3B). In some implementations, the switch box 110 fully encloses the transceiver module and the associated cooling structure. The switch box is mechanically mounted on the rack structure. The transceiver module is configured to convert a plurality of incoming signals (e.g., optical signals) to a plurality of outgoing signals (e.g., optical or electrical signals) and generate heat while the plurality of incoming signals are converted. The cooling structure is coupled to the transceiver module. The cooling structure includes an inlet and an outlet, and is configured to inject a coolant via the inlet and output the coolant via the outlet, thereby allowing the coolant to at least partially carry away the heat generated by the transceiver module.

FIG. 1B is an example data center 150 including a hierarchy of servers 120 organized on a plurality of server racks 100, in accordance with some embodiments. The data center 150 is applied in cloud computing to implement different types of tasks, e.g., for artificial intelligence (AI), high performance computing (HPC), networking, and/or storage data management. The data center 150 may include a physical facility that houses computing machines and their related hardware equipment, such as servers 120, data storage devices 116, and network equipment. The data center 150 is applied to provide cloud-based service.

In some embodiments, the hierarchy of servers 120 of the data center 150 includes three levels of servers (e.g., core servers 120C, spine servers 120S, leaf servers 120L). On each level, a respective server rack 100 includes a set of respective severs 120. A server rack 100 including the core servers 120C is communicatively coupled to a server rack 100 including the spine servers 120S via a plurality of first communication paths 152 (e.g., extending for a distance of 2 kilometers or below). A server rack 100 including the spine servers 120S is communicatively coupled to a server rack 100 including the leave servers 120L via a plurality of second communication paths 154 (e.g., extending for a distance of 100 meters or less). Each leave server rack 100L includes and organizes a set of leave servers 120L. The switch box 110 of each leave server rack 100L is communicatively coupled to another switch box 110 or leave servers 120L disposed on an adjacent leave server rack via a plurality of third communication paths 156 (e.g., extending for a distance of 20 meters or less). The switch box 110 of each leave server rack 100L is communicatively coupled to the leave servers 120L on the same leave server rack 100L via a plurality of fourth communication paths (e.g., approximately having a length of 2 meters or less). Stated another way, the communication paths may be applied on different levels of the data center 150, e.g., inside each server rack 100 (e.g., from the switch box 110 to the servers 120 in FIG. 1A), among adjacent server racks 100, from the leave servers 120L to the spine servers 120S, and from the spine servers 120S to the core servers 120C.

Independently of the level of servers 120, the corresponding communication path 152, 154, or 156 has a signal-to-noise ratio lower than a respective threshold corresponding to their targeted data transfer rate. For example, a target data transfer rate on the communication paths 152, 154, and 156 is 1.6 Tb/s, 3.2 Tb/s, or above. Each communication path (e.g., path 154A) is coupled between an origin server (e.g., server 120SA) that generates data to be transferred and a destination server (e.g., server 120LA) that receives data to be transferred. The greater the data transfer rate, the greater heat generated by transceiver modules of the origin server and the destination server. In various embodiments of this application, heat generated by the transceiver modules are efficiently dissipated by using a cooling structure directly on each transceiver module, such that the signal-to-noise ratio can be controlled to sustain the target data transfer rate (e.g., 1.6 Tb/s, 3.2 Tb/s, or above).

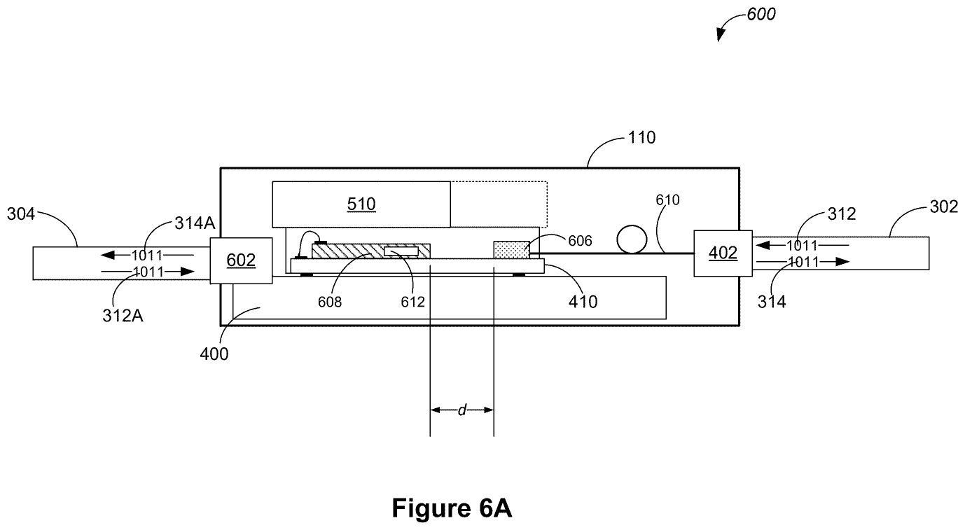

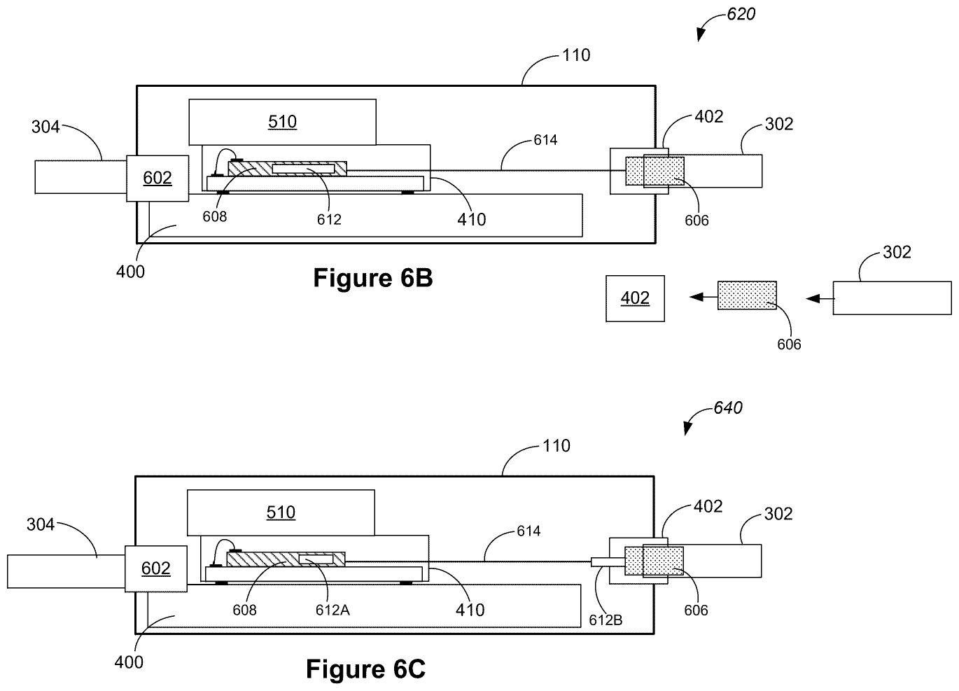

Under some circumstances, large language model (LLM), autonomous driving, generative AI, and cloud-based services require that the data centers 150 to provide substantial bandwidth capabilities and data transfer rates. For example, a target data transfer rate of 1.6 Tb/s or 3.2 Tb/s may be required for in-rack and rack-to-rack data communication to support the data center 150 (e.g., implementing a content security policy (CSP) or machine learning). A conventional pluggable optics increase at a much slower data transfer rate than that of data center traffic. Global data centers may have a data rate increasing from 400 Gbps and 800 Gbps to 1.6 Tb/s with a greater data bandwidth and a lower data latency. A gap between application requirements and the capability of conventional pluggable optics keeps increasing. In some embodiments, co-packaged optics (CPO) or linear-drive pluggable optics (LPO) increases an interconnect bandwidth density and energy efficiency by shortening an electrical link length, which is accomplished through packaging and co-optimization of electronics and photonics wafer. More details on a CPO scheme and a LPO scheme are discussed below with reference to FIGS. 6A-6C.

In some situations, in-rack and rack-to-rack clustering Ethernet speeds correspond to an error rate induced by thermal dissipation. The higher temperatures of the transceivers associated with the optical fibers, the less efficient data communication, and the slower the data transfer rates. In some embodiments, an integrated electro-laser transceiver component is disposed at each optical fiber port, and operates with power consumption for which heat cannot be dissipated efficiently and results in a high bit error rate. For example, an integrated transceiver component uses power consumptions of 5-17 W, when the data transfer rate is below 1 Tb/s. In some implementations, the data transfer rates of 1.6 Tb/s and 3.2 Tb/s require power consumptions of 25 W and 35 W, respectively. Given the amount of heat that needs to be dissipated, these power consumption levels may limit these transceiver components from being used in a data center having a substantially high target data transfer rate (e.g., 1.6 Tb/s or 3.2 Tb/s). In some embodiments of this application, a transceiver module may consolidate optical engines associated fiber optics and/or associated switching ASIC in a switching box and away from associated fiber ports, allowing a cooling structure to absorb and transport heat generated by the transceiver module in a centralized manner.

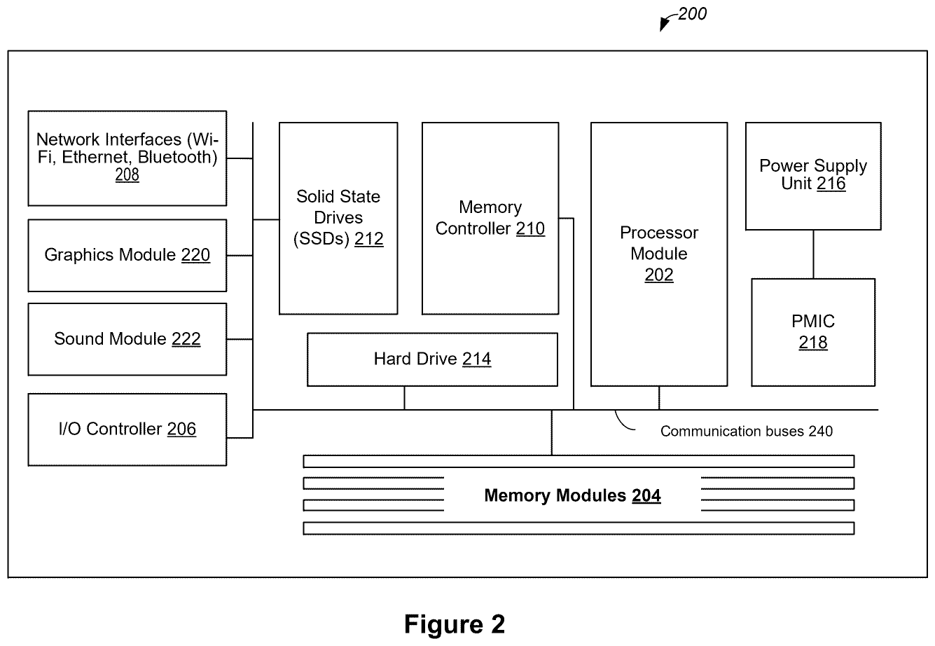

FIG. 2 is a block diagram of an example system module 200 in a typical computer device, which may be applied as a server 120 in FIG. 1, in accordance with some embodiments. The system module 200 in this computer device includes at least a processor module 202, memory modules 204 for storing programs, instructions and data, an input/output (I/O) controller 206, one or more communication interfaces such as network interfaces 208, and one or more communication buses 240 for interconnecting these components. In some embodiments, the I/O controller 206 allows the processor module 202 to communicate with an I/O device (e.g., a keyboard, a mouse or a track-pad) via a universal serial bus interface. In some embodiments, the network interfaces 208 includes one or more interfaces for Wi-Fi, Ethernet and Bluetooth networks, each allowing the computer device to exchange data with an external source, e.g., a server or another computer device. In some embodiments, the communication buses 240 include circuitry (sometimes called a chipset) that interconnects and controls communications among various system components included in system module 200.

In some embodiments, the memory modules 204 include high-speed random-access memory, such as DRAM, static random-access memory (SRAM), double data rate (DDR) dynamic random-access memory (RAM), or other random-access solid state memory devices. In some embodiments, the memory modules 204 include non-volatile memory, such as one or more magnetic disk storage devices, optical disk storage devices, flash memory devices, or other non-volatile solid state storage devices. In some embodiments, the memory modules 204, or alternatively the non-volatile memory device(s) within the memory modules 204, include a non-transitory computer readable storage medium. In some embodiments, memory slots are reserved on the system module 200 for receiving the memory modules 204. Once inserted into the memory slots, the memory modules 204 are integrated into the system module 200.

In some embodiments, the system module 200 further includes one or more components selected from a memory controller 210, solid state drives (SSDs) 212, a hard disk drive (HDD) 214, a power supply unit (PSU) 216, power management integrated circuit (PMIC) 218, a graphics module 220, and a sound module 222. The memory controller 210 is configured to control communication between the processor module 202 and memory components, including the memory modules 204, in the computer device. The SSDs 212 are configured to apply integrated circuit assemblies to store data in the computer device, and in many embodiments, are based on NAND or NOR memory configurations. The HDD 214 is a conventional data storage device used for storing and retrieving digital information based on electromechanical magnetic disks. The PSU 216 is configured to receive an external power supply and provide a plurality of DC power supplies (e.g., 12V, 54V). The PMIC 218 is configured to modulate the plurality of DC power supplies to other desired DC voltage levels, e.g., 5V, 3.3V or 1.8V, as required by various components or circuits (e.g., the processor module 202) within the computer device. The graphics module 220 is configured to generate a feed of output images to one or more display devices according to their desirable image/video formats. The sound module 222 is configured to facilitate the input and output of audio signals to and from the computer device under control of computer programs.

It is noted that communication buses 240 also interconnect and control communications among various system components including components 210-222.

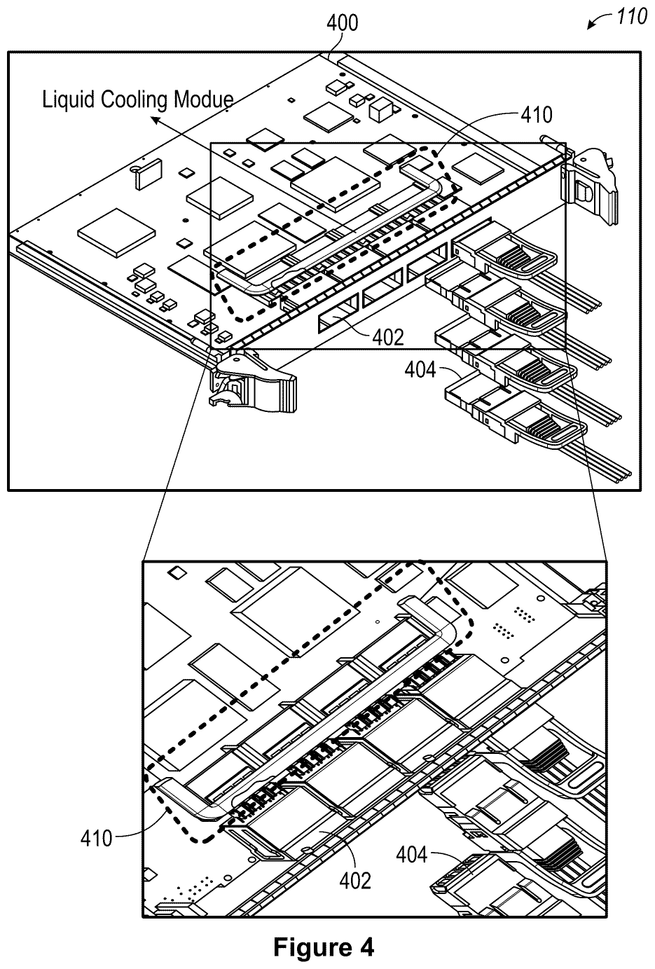

FIGS. 3A and 3B are two simplified front views of an example server rack 100 including a switch box 110, in accordance with some embodiments. Some implementations of the server rack 100 include a rack structure (e.g., including a frame 102 and a plurality of slots 104 in FIG. 1) for supporting one or more rack servers 120. The switch box 110 is mechanically mounted on the rack structure (e.g., on a top slot of the server rack 100), and is configured to receive a plurality of detachable optical interconnects 302. The switch box 110 includes a transceiver module (e.g., module 410 in FIG. 4) configured to convert a plurality of incoming signals 312 to a plurality of outgoing signals 314 and output the plurality of outgoing signals 314.

Referring to FIG. 3A, in some embodiments, the one or more rack servers 120 are configured to receive the plurality of outgoing signals 314 (e.g., optical or electrical signals) via a plurality of outgoing interconnects 304. Further, in some embodiments, the plurality of incoming signals 312 include a set of optical signals received via the plurality of detachable optical interconnects 302, and the plurality of outgoing signals 314 includes a set of electrical signals 314A that are configured to be transmitted to the one or more rack servers 120. Alternatively or additionally, in some embodiments, the plurality of outgoing signals 314 includes a set of outgoing optical signals 314B that are configured to be transmitted to the one or more rack servers 120. The plurality of outgoing signals 314 may include electrical signals 314A only, optical signals 314B only, or a combination thereof.

Conversely, referring to FIG. 3B, in some embodiments, the one or more rack servers 120 are configured to provide the plurality of incoming signals 312 to the switch box 110. Further, in some embodiments, the plurality of incoming signals 312 include a set of electrical signals 312A provided by the one or more rack servers 120, and the plurality of outgoing signals 314 includes a set of optical signals transmitted via the plurality of detachable optical interconnects 302. Alternatively or additionally, in some embodiments, the plurality of incoming signals 312 include a set of incoming optical signals 312B provided by the one or more rack servers 120. The plurality of incoming signals 312 may include electrical signals 312A only, optical signals 312B only, or a combination thereof.

FIG. 4 illustrates a perspective view of a main board 400 of an example switch box 110 and a zoom-in view of a transceiver module 410 disposed on the main board 400, in accordance with some embodiments. The switch box 110 is mechanically mounted on a rack structure (e.g., a slot 104 of a server rack 100) for supporting one or more rack servers 120 (FIG. 1). The switch box 110 includes the transceiver module 410 that may be disposed on the main board 400, and is configured to receive a plurality of detachable optical interconnects 302. The transceiver module 410 is configured to convert a plurality of incoming signals 312 to a plurality of outgoing signals 314 and generate heat while converting the plurality of incoming signals 312. In some embodiments, the switch box 110 further includes a plurality of fiber ports 402 configured to receive the plurality of detachable optical interconnects 302. The plurality of detachable optical interconnects 302 are coupled to transceiver module 410, and may provide optical signals as the plurality of incoming signals 312 or receive optical signals as the plurality of outgoing signals 314.

In some embodiments, each of the plurality of detachable optical interconnects 302 includes an interconnector port 404 configured to mate a respective fiber port 402 via a fastening structure and mechanically secure an end of the respective optical interconnect 302 onto the switch box 110. Optical signals can be exchanged between the transceiver module 410 and each detachable optical interconnect 302 by way of a respective interconnector port 404 and the respective fiber port 402. Stated another way, in some embodiments, the detachable optical interconnects 302 do not include optical engines within their fiber ports 402, and the optical engines of the detachable optical interconnects 302 are consolidated in the transceiver module 410, which is disposed on the main board 400 of the switch box 110.

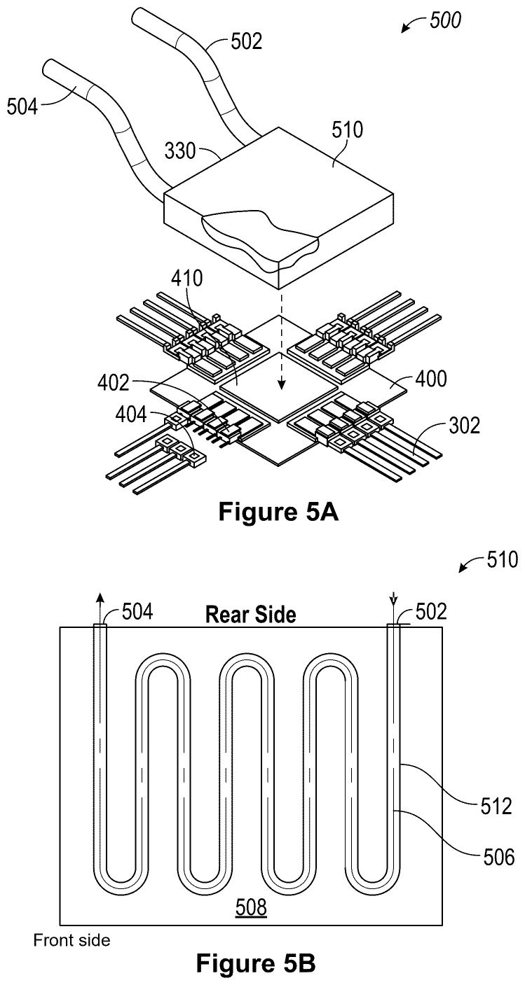

When the optical engines of the detachable optical interconnects 302 are moved into the switch box 110, a size of the interconnector port 404 of each optical interconnect 302 is reduced compared with the interconnector port 404 including a respective optical engine. This arrangement allows a larger number of interconnects 302 to enter a limited interface space of the switch box 110, thereby increasing a port density of the switch box 110. Further, the transceiver module 410 has a compact form factor, and heat generated by the transceiver module 410 may be dissipated by a cooling structure (e.g., a metallic plate). Conversely, in some situations, for each detachable optical interconnect 302, even if a space in the interconnector port 404 can accommodate a respective optical engine, few heat dissipation mechanism can fit into the space to dissipate heat generated by the transceiver module 410 efficiently. Stated another way, in some implementations, the transceiver module 410 is configured to integrate optical engines of the interconnector ports 404 of the detachable optical interconnect 302. When integrated in the switch box 110, the transceiver module 410 is compatible with a cooling structure (e.g., structure 510 in FIGS. 5A and 5B) for dissipating heat in a consolidated manner,. By these means, application of the transceiver module 410 increases a port density of the switch box 110 used by a data center server system and overcomes thermal challenges in high speed data transfer (e.g., at 1.6 Tb/s, 3.2 Tb/s).

FIG. 5A is an expanded perspective view of an integrated module 500 including a cooling structure 510 and a transceiver module 410 coupled to the cooling structure 510, in accordance with some embodiments. FIG. 5B is a top see-through view of an example cooling structure 510 coupled to the transceiver module 410 shown in FIG. 5A, in accordance with some embodiments. In some embodiments, both the cooling structure 510 and the transceiver module 410 are enclosed in a switch box 110 (not shown in FIG. 5A), which is mounted on a server rack 100 (FIG. 1). For example, the switch box 110 is mechanically mounted on a rack structure (e.g., a topmost slot 104 of a server rack 100) for supporting one or more rack servers 120 (FIG. 1), and the transceiver module 410 may be disposed on the main board 400 of the switch box 110 (FIG. 4). In some situations, the switch box 110 may be mechanically fixed on, and inseparable from, the rack structure using manual manipulation without using a tool. The switch box 110 is configured to receive a plurality of detachable optical interconnects 302. The transceiver module 418 includes a plurality of optical engines (e.g., 606 in FIG. 6A) configured to convert a plurality of incoming signals 312 to a plurality of outgoing signals 314 (FIGS. 3A and 3B) and generate heat while converting the plurality of incoming signals 312.

In some implementations, the cooling structure 510 is coupled to the transceiver module 410. For example, a bottom surface of the cooling structure 510 may at least partially keep in contact with a top surface of the transceiver module 410 for absorbing the heat generated by the transceiver module 410. The cooling structure 510 includes an inlet 502 and an outlet 504, and is configured to inject a coolant 506 (FIG. 5B) via the inlet 502 and output the coolant 506 via the outlet 504, thereby allowing the coolant 506 to at least partially carry away the heat generated by, and absorbed from, the transceiver module 410.

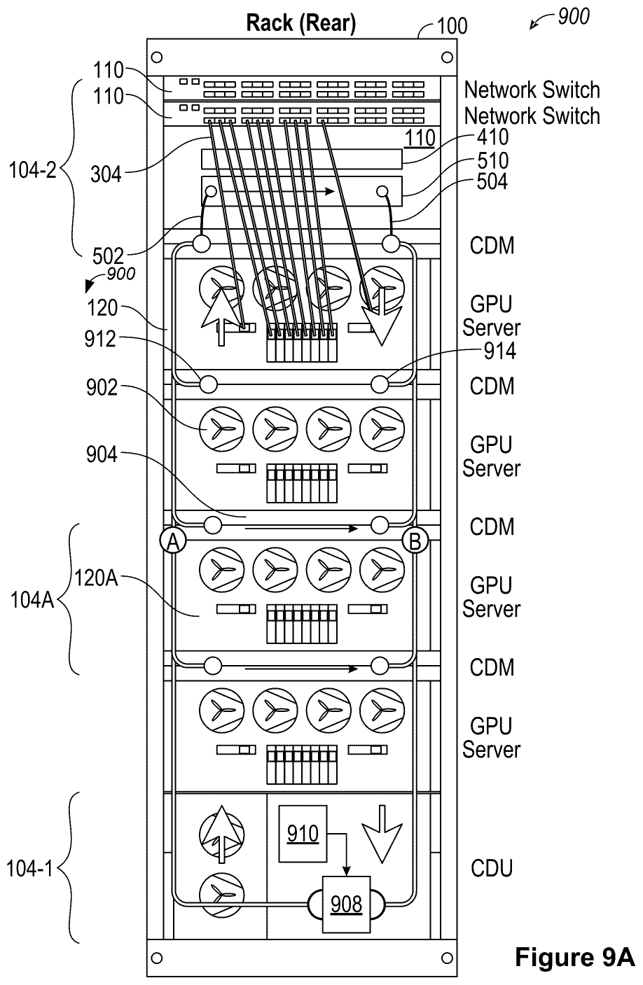

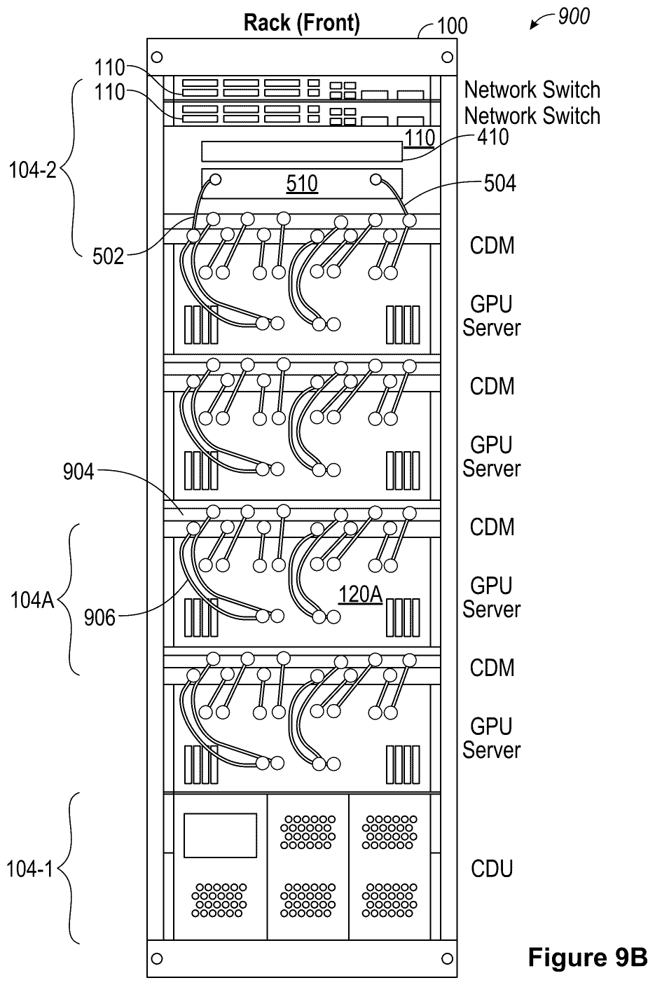

In some embodiments, the cooling structure 510 may be coupled to the transceiver module 410 via an adhesive or a fastener structure. In some embodiments, the transceiver module 410 and the cooling structure 510 are inseparable from one another using manual manipulation without using a tool. At least one of the transceiver module 410 and the cooling structure 510 may be mechanically fixed on, and inseparable from, the switch box 110 using manual manipulation without using a tool. In some embodiments, the rack structure associated with the server rack 100 includes a first slot (e.g., 104-2 in FIG. 9A) configured to receive the switch box 110 that encloses the transceiver module 410 and the cooling structure 510, allowing the switch box 110 to be detached from the server rack 100. The transceiver module 410 and the cooling structure 510 may be replaced, separately or jointly, on the main board 400 of the switch box 110.

In some embodiments, a plurality of fiber ports 402 of the switch box 110 are coupled to one or more edges (e.g., one, two, three, or four edges) of the main board 400. The transceiver module 510 is coupled to the plurality of detachable optical interconnects 302 via the plurality of fiber ports 402 and a plurality of interconnector ports 404 (FIG. 4). The optical interconnects 302 may provide the plurality of incoming signals 312 or carry away the plurality of outgoing signals 314. In some embodiments, the plurality of detachable optical interconnects 302 received by the interconnect ports 404 have a data communication bandwidth greater than a threshold bandwidth (e.g., 1 Tb/s), and the transceiver module 410 has a power consumption level greater than 25 W. For example, the data bandwidth of the detachable optical interconnects 302 is 1.6 Tb/s or 3.2 Tb/s. More details on signal transmission are discussed above with reference to FIGS. 3A and 3B.

Referring to FIG. 5B, in some embodiments, the cooling structure 510 acts as a heat sink and a heat dissipator, and includes a metallic plate 508. The metallic plate 508 comes into contact with the transceiver module 410 via a contact surface for absorbing the heat generated by the transceiver module 410. In some embodiments, the metallic plate 508 includes one or more of: admiralty brass, aluminum, aluminum brass, carbon steel, copper, cupronickel 70/30 and cupronickel 90/10, an alloy of nickel and copper (also called Monel alloys), and stainless steel (e.g., duplex or super duplex grade). Further, in some embodiments, the metallic plate 508 includes a coolant channel 512 sealed within the metallic plate 508, and each of the inlet 502 and the outlet 504 is coupled to a respective edge 330 of the metallic plate and connected to a respective end of the coolant channel 512. The coolant channel 512 may have a serpentine shape and extend substantially parallel to the contact surface from the inlet 502 to the outlet 504.

Additionally, in some embodiments, the metallic plate 508 has a height greater than a threshold dimension, e.g., comparable to or greater than a length or a width of the metallic plate 508, forming a metallic block. The coolant channel 512 may be extended in a three dimensional body of the metallic block. In some implementations, the coolant channel 512 extends along a plurality of parallel layers each of which is substantially parallel or perpendicular to the contact surface of the metallic plate 508 and the transceiver module 410. Particularly, in an example not illustrated, the coolant channel 512 extends successively from a bottom layer adjacent and parallel to the contact surface to each upper layer above the bottom layer parallel to the contact surface.

FIGS. 6A-6C are cross sectional views 600, 620, and 640 of example switch boxes 110, in accordance with some embodiments. The switch box 110 includes a main board 400, a transceiver module 410 mounted on the main board 400, a fiber port 402 coupled to the main board 400, and a server-side port 602. In some embodiments, each of the fiber port 402 and the server-side port 602 are coupled to a respective edge of the main board 400 and exposed from a respective side of the switch box 110. The fiber port 402 and the server-side port 602 are configured for receiving a respective detachable optical interconnect 302 and a server-side interconnect 304 (e.g., carrying an optical or electrical signal), respectively.

In some embodiments, the transceiver module 410 further includes a optical engine 606 and a switching ASIC 608. The optical engine 606 is coupled to each fiber port 402 via an optical cable 610, and is configured to convert an incoming optical signal 312 (FIG. 3A) to an intermediate electrical signal that is further processed by the switching ASIC 608 to generate an outgoing electrical signal 314A. The incoming optical signal 312 is provided by the respective detachable optical interconnect 302 by way of the fiber port 402 and the optical cable 610 disposed in the switch box 110. Conversely, the switching ASIC 608 is configured to convert an incoming electrical signal 312A (FIG. 3B) to another intermediate electrical signal that drives the optical engine 606 to generate an outgoing signal 314 fed into the optical cable 610. The outgoing signal 314 is an optical signal provided to the respective detachable optical interconnect 302 by way of the fiber port 402 and the optical cable 610.

In some embodiments, the transceiver module 410 has a larger surface arca than, and entirely covers, the transceiver module 410. Under some circumstances, heat is generated primarily by the switching ASIC 608, which may include a digital signal processing (DSP) circuit 612. The cooling structure 510 is aligned with a region corresponding to the switching ASIC 608 to dissipate the heat generated by the switching ASIC 608. The cooling structure 510 relies on liquid cooling to dissipate the heat generated by the switching ASIC 608. Referring to FIG. 6A, in some embodiments, the optical engine 606 is coupled to the main board 400 jointly with the switching ASIC 608, while maintaining a separation d from the switching ASIC 608. The separation d reduces an impact of the heat generated by the switching ASIC 608 on operation of the optical engine 606.

Referring to FIG. 6B, in some embodiments, the optical engine 606 includes an optical pluggable module that is separate from the transceiver module 410 including the switching ASIC 608. The optical pluggable module is mechanically coupled to the fiber port 402 in a pluggable manner. In some embodiments, the optical pluggable module corresponding to the optical engine 606 is plugged into the fiber port 402, and automatically aligned and connected to an electrical switching cable 614. After the optical engine 606 is plugged into the fiber port 402, a corresponding detachable optical interconnects 302 is further plugged into the fiber port 402, and automatically aligned and connected to an input of the optical engine 606. When the detachable optical interconnect 302 is detached, it is optionally detached with or without the optical engine 606. In these implementations, the effect of liquid cooling made by the cooling structure 510 is further supplemented by separation or isolation of the switching ASIC 608 from the optical pluggable module (e.g., optical engine 606 in FIG. 6B). The switching ASIC 608 may be cooled down to a relatively low operational temperature (e.g., below 60° C.) to avoid an over-heating issue that comprises an associated transmission error rate, particularly when the data transfer rate goes beyond a certain threshold rate (e.g., to 1.6 Tb/s, 3.2 Tb/s; 6.4 Tb/s, and 12 Tb/s).

In some embodiments, the switching ASIC 608 includes a DSP circuit 612, which further includes a first DSP block 612A and a second DSP block 612B. Referring to FIG. 6C, the first DSP block 612A is integrated in the switching ASIC 608, and the second DSP block 612B is coupled to, or integrated with, the optical engine 606 in the optical pluggable module. The second DSP block 612B is physically separate from the transceiver module 410. The second DSP block 612B is configured to receive and process an output signal of the optical engine 606 and provide an output signal to the transceiver module 410 via the electrical switching cable 614.

In other words, in some embodiments, the switch box 110 in FIG. 6A is formed according to a co-packaged optics (CPO) scheme. Optics (e.g., the optical engine 606) and silicon (e.g., the switching ASIC 608) are integrated on a single packaged substrate (e.g., to address data bandwidth and power consumption issues. The single packaged CPO-based substrate is configured to support fiber optics, digital signal processing (DSP), switch ASICs, and packaging and may be applied in a data center and cloud infrastructure. Alternatively, in some embodiments, the switch box 110 in FIG. 6B or 6C is formed according to a linear-drive pluggable optics (LPO) scheme, which a utilizes an optical pluggable module. Further, in various embodiments, different levels of physical separation between the switching ASIC 608 and the optical engine 606 in FIGS. 6A-6C help reduce the impact of the heat generated by the switching ASIC 608 on performance of the optical engine 606. The cooling structure 510 may be coupled to a CPO-based or LPO-based substrate (e.g., main board 400), which further helps reduce the impact of the heat on performance of the optical engine 606.

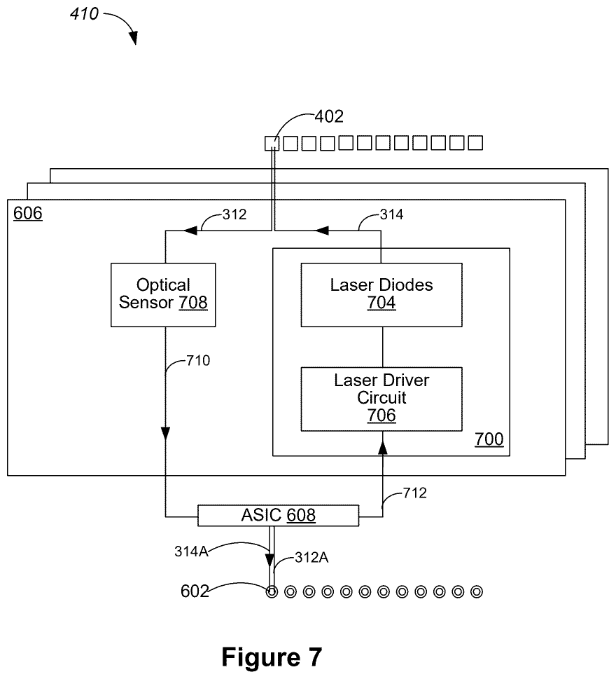

FIG. 7 is a block diagram of a transceiver module 410 coupled between a fiber port 402 and a server-side port 602 of a switch box 110, in accordance with some embodiments. In some embodiments, the transceiver module 410 is enclosed in the switch box 110 and includes an switching ASIC 608 and a plurality of optical engines 606 (FIG. 6). Each optical engine 606 may exchange signals with a duplex optical interconnector (e.g., a duplex fiber cable). Alternatively, each optical engine 606 may exchange signals with a plurality of duplex optical interconnectors in a time-multiplexed manner. Each optical engine 606 includes a transmitter 700 (e.g. a laser diode 704 and a laser driver circuit 706) and a receiver (e.g., one or more optical sensors 708). In an example, the laser diode 704 includes a vertical-cavity surface-emitting laser (VCSEL) diode. In another example, the laser diode 704 is distinct from the VCSEL diode. The one or more optical sensors 708 are configured to receiving an incoming optical signal 312 and convert the incoming optical signal 312 to an intermediate electrical signal 710, which is processed by the switching ASIC 608 to generate an electrical signal 314A. In some embodiments, the switching ASIC 608 receives an incoming electrical signal 312A and converts it to an electrical signal 712. The electrical signal 712 controls the laser driver circuit 706 to drive the laser diode 704 to emit an outgoing optical signal 314.

In some embodiments, a server rack 100 includes a plurality of optical engines 606, which are configured to generate a plurality of outgoing optical signals 314. The transceiver module 410 includes the plurality of transmitters 700, i.e., includes a plurality of laser diodes 704 and a plurality of laser driver circuits 706 coupled to the plurality of laser diodes 704. The laser diodes 704 are configured to emit the set of optical signals 314 to be transmitted via the plurality of detachable optical interconnects 302. The plurality of laser driver circuits 706 are configured to receive the plurality of incoming signals 312, provide electrical signals 712 to drive the plurality of laser driver circuits 706, and generate the set of optical signals 314.

In some embodiments, outgoing signals of the switch box 110 include a set of electrical signals 314A, and incoming signals of the switch box 110 include a set of optical signals 312. The transceiver module 410 includes a plurality of receivers (e.g., optical sensors 708) configured to convert the set of optical signals 312 to the set of electrical signals 314A, e.g., jointly with the switching ASIC 608. The set of electrical signals 314A may be further transmitted to the one or more rack servers 120 using a plurality of electrical interconnects 304 (FIG. 3A).

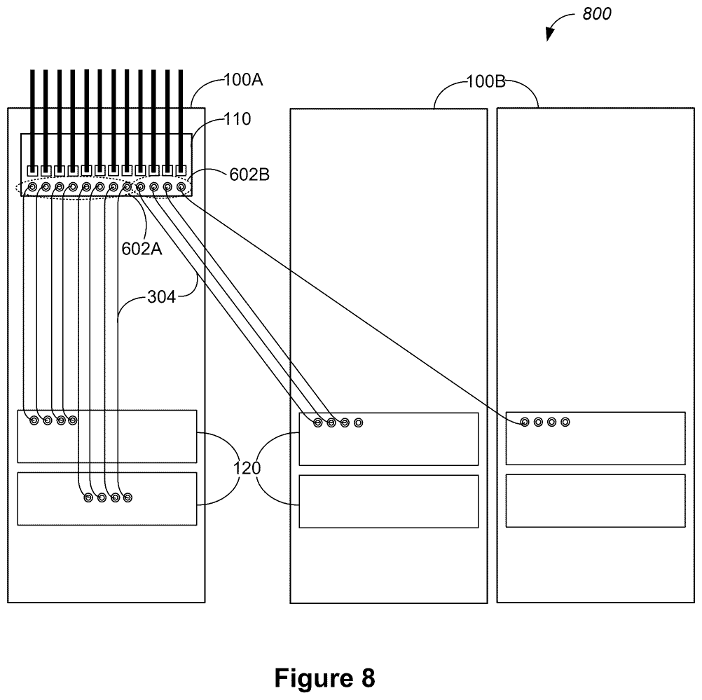

FIG. 8 illustrates a server group 800 including a plurality of servers 120, in accordance with some embodiments. The plurality of servers 120 are coupled to one other and distributed on a plurality of server racks 100. The plurality of server racks include a first server rack 100A. In some embodiments, a switch box 110 of the first server rack 100A includes a first set of ports 602A configured to receive a plurality of detachable electrical interconnects 304, and each of the first set of ports 602A is configured to exchange electrical signals with a respective rack server 120 mounted on the rack structure of the first server rack 100A. Alternatively or additionally, in some embodiments, the switch box 110 of the first server rack 100A further includes a second set of ports 602B, which is coupled to a plurality of rack servers 120 on a set of one or more alternative server racks 100B. Each alternative server rack 100B includes at least one rack server 120 electrically coupled to a respective port of the second set of ports 602B of the first server rack 100A. It is noted that, in various embodiments of this application, the switch box 110 of the first server rack 100A includes the first set of ports 602A only, the second set of ports 602B only, or a combination thereof.

FIG. 9A is a rear view of an example server rack 100 including a server cooling system 900, in accordance with some embodiments, and FIG. 9B is a front view of another example server rack 100 including a server cooling system 900, in accordance with some embodiments. The server cooling system 900 relies on liquid cooling. In some embodiments, the server rack 100 including the server cooling system 900 is applied in a data center applied to implement machine learning tasks (e.g., training deep neural networks, executing large language models (LLM)). The server rack 100 includes a plurality of slots 104 for receiving and supporting a respective computing equipment module 106 (e.g., a GPU server 120). In some embodiments, the server rack 100 further includes a cooling distribution module (CDM) disposed between two immediately adjacent slots 104. Stated another way, each CDM is disposed under a bottom plate of a respective upper slot or above an upper plate of a respective bottom slot. Each CDM includes a respective coolant channel embedded in a heat sink. When a coolant (e.g., water) flows through the respective coolant channel of each CDM, the coolant at least partially carries away heat absorbed from immediately adjacent computing equipment modules 106 by the heat sink. Referring to FIGS. 9A and 9B, in this example, a CDM is optionally disposed between two GPU servers or between a GPU server and a switch box 110.

Each CDM has an inlet 912 and an outlet 914, and is coupled to a cooling distribution unit (CDU) that acts as an engine to drive the coolant through the cooling system 900, allowing the coolant to be injected into the inlet 912 of each CDM and collected from the outlet 914 of each CDM. The CDU may regulate and control a flow of the coolant, and maintain desired temperature and flow rate. In some embodiments (FIG. 9A), the CDMs may be arranged in parallel to one another and coupled between an inlet and an outlet of the CDU. In some embodiments (not shown), the CDMs may be arranged in series with one another and coupled between an inlet and an outlet of the CDU. Referring to FIG. 9A, in some embodiments, each GPU server 120 or the CDU includes one or more respective fans 902 within an associated free slot space, and each respective fans 902 is configured to enhance circulation of air and increase heat dissipation via air convection in the respective slot 104.

In some embodiments, a transceiver module 410 and an associated cooling structure 510 are disposed inside a switch box 110. Alternatively, in some embodiments, the transceiver module 410 and associated cooling structure 510 are disposed between a switch box 110 and a CDM. Referring to FIG. 9B, an inlet 502 and an outlet 504 of the cooling structure 510 may be connected to one of the CDMs disposed on the server rack 100. A coolant is injected through the CDMs and the cooling structure 510 to dissipate heat generated by the transceiver module 410 jointly with heat generated by the servers 120.

Referring to FIG. 9A, in some embodiments, a CDM is coupled to a neighboring server 120 and dissipates heat generated by the neighboring server 120 as whole. The rack structure of the server rack 100 further includes a server tray 104A configured to receive a first rack server 120A. While the coolant 506 (FIG. 5B) runs through the cooling structure 510, the CDM 904 disposed immediately above the first rack server 120A injects a second coolant and output the second coolant in parallel with the cooling structure 510 associated with the transceiver module 410, thereby allowing the second coolant to at least partially carry away the heat generated by the first rack server 120A.

In some embodiments, the switch box 110 is optically coupled to the servers 120 on the same server rack 100 using a plurality of server-side interconnect 304 (e.g., corresponding to an optical communication channel). Alternatively, in some embodiments, the switch box 110 is electrically coupled to the servers 120 on the same server rack 100 using a plurality of server-side interconnect 304 (e.g., corresponding to an electrical communication channel).

Referring to FIG. 9B, in some embodiments, on a front side of the server rack 100, the CDM 904 has a plurality of connectors 906 coupled to cooling structures within the first rack server 120A. More specifically, the cooling structure 510 associated with the transceiver module 410 includes a first cooling structure, and the server tray 104A further includes a second cooling structure, which is configured to inject a second coolant and output the second coolant in parallel with the first cooling structure, thereby allowing the second coolant to at least partially carry away the heat generated by the first rack server 120A. In some embodiments, a first coolant running through the first cooling structure 510 is split from the second coolant running through the first rack server 120A (e.g. at location A in FIG. 9A) before it enters the inlet 502, and merges with the second coolant (e.g., at location B in FIG. 9A) after it exits the outlet 504.

In some embodiments, a coolant pump 908 is coupled between the inlet 502 and the outlet 504. A coolant controller 910 is coupled to the coolant pump 908, and configured to control the coolant pump 908 to push the coolant 506 into the inlet 502 of the cooling structure 510 and draw the coolant 506 out of the outlet 504 of the cooling structure 510. Further, in some embodiments, the coolant pump 908 is disposed in a first tray 104-1 (e.g., a bottommost tray) of the server rack 100, and the transceiver module 410 is disposed in a second tray 104-2 of the server rack 100 that is distinct from the first tray 104-1.

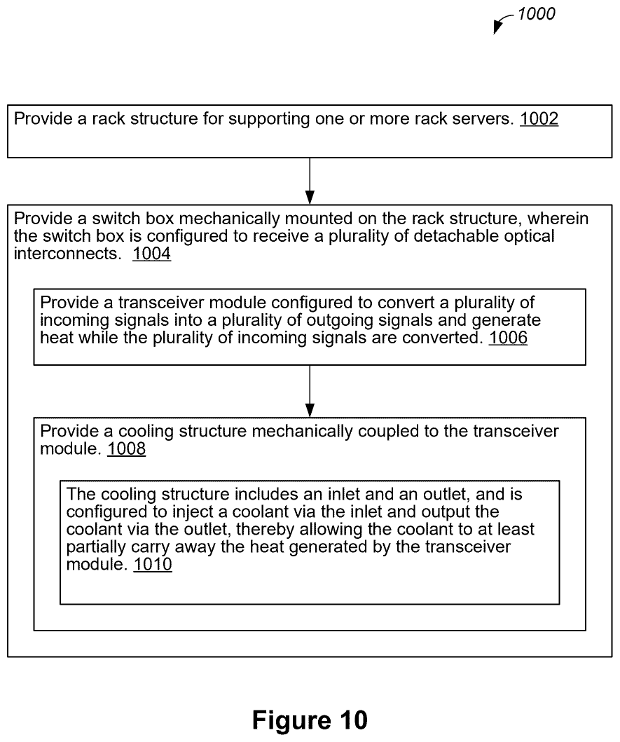

FIG. 10 is a flow diagram of a method 1000 for providing a server rack 100, in accordance with some embodiments. A rack structure is provided (operation 1002) for supporting one or more rack servers 120. A switch box 110 is provided (operation 1004). The switch box 110 is mechanically mounted on the rack structure, and configured to receive a plurality of detachable optical interconnects 302. A transceiver module 410 is provided (operation 1006) in the switch box. The transceiver module 410 is configured to convert a plurality of incoming signals (e.g., optical signal 312 in FIG. 3A, electrical signals 312A in FIG. 3B) to a plurality of outgoing signals (e.g., electrical signal 314A in FIG. 3A, optical signals 314 in FIG. 3B) and generate heat while the plurality of incoming signals are converted. A cooling structure 510 is provided (operation 1008) in the switch box 110. The cooling structure 510 is coupled to the transceiver module 410. The cooling structure 510 includes (operation 1010) an inlet 502 and an outlet 504, and is configured to inject a coolant 506 via the inlet 502 and output the coolant 506 via the outlet 504, thereby allowing the coolant 506 to at least partially carry away the heat generated by the transceiver module 410.

In some embodiments (FIGS. 5A and 5B), the cooling structure 510 includes a metallic plate having a contact surface, and the metallic plate comes into contact with the transceiver module 410 via the contact surface for absorbing the heat generated by the transceiver module 410. Further, in some embodiments, the metallic plate includes a coolant channel 512 sealed within the metallic plate, and each of the inlet 502 and the outlet 504 is coupled to a respective edge of the metallic plate and connected to a respective end of the coolant channel 512. The coolant channel 512 extends substantially parallel to the contact surface from the inlet 502 to the outlet 504.

In some embodiments, the switch box 110 further includes a first set of ports (e.g., server-side ports 602A in FIG. 8) configured to receive a plurality of detachable electrical interconnects 304, and each of the first set of ports is configured to exchange electrical signals with a respective rack server 120 mounted on the rack structure.

In some embodiments, the switch box 110 further includes a second set of ports (e.g., server-side ports 602B in FIG. 8) configured to receive a plurality of detachable electrical interconnects 304, and the second set of ports is coupled to a plurality of rack server 120 on a set of one or more alternative server racks 100B. Each alternative server rack 100 100B includes at least one rack server 120 electrically coupled to a respective port of the second set of ports.

In some embodiments, the transceiver module 410 and the cooling structure 510 are inseparable from one another using manual manipulation without using a tool, the rack structure includes a first slot 104-1 configured to receive the switch box 110 including the transceiver module 410 and the cooling structure 510, allowing the switch box 110 to be detached from the server rack 100 and the transceiver module 410 and the cooling structure 510 to be replaced in the switch box 110.

In some embodiments, at least one of the transceiver module 410 and the cooling structure 510 is mechanically fixed on, and inseparable from, the switch box 110 using manual manipulation without using a tool.

In some embodiments, the transceiver module 410 includes a plurality of optical engines 606 and a switching ASIC 608 (FIG. 6A). The plurality of optical engines 606 are configured to exchange optical signals with the plurality of detachable optical interconnects 302, and the switching ASIC 608 is configured to exchange electrical signals with the plurality of optical engines 606.

In some embodiments (FIGS. 6B and 6C), the transceiver module 410 includes a switching ASIC 608, and the switch box 110 further includes a plurality of optical engines 606 that are distinct from, and electrically coupled to, the transceiver module 410. Further, in some embodiments (FIGS. 6B and 6C), the switch box 110 is configured to receive the plurality of detachable optical interconnects 302 via a plurality of fiber ports 402, and each of the plurality of optical engines 606 is detachably coupled to a respective fiber port 402. Additionally, in some embodiments (FIG. 6C), the switching ASIC 608 of the transceiver module 410 is electrically coupled to the plurality of optical engines 606 via an electrical switching cable 614, and the plurality of optical engines 606 further include a DSP block 612B configured to exchange a digital electrical signal with the switching ASIC 608 via the electrical switching cable 614.

In some embodiments (FIG. 7), the plurality of outgoing signals include a set of optical signals, and the transceiver module 410 further includes a plurality of laser diodes 704 and a plurality of laser driver circuits 706 coupled to the plurality of laser diodes 704. The laser diodes 704 are configured to emit the set of optical signals to be transmitted via the plurality of detachable optical interconnects 302. The plurality of laser driver circuits 706 are configured to receive the plurality of incoming signals, and provide electrical signals to drive the laser diodes 704 to generate the set of optical signals.

In some embodiments, the plurality of outgoing signals include a set of electrical signals and the plurality of incoming signals include a set of optical signals, and the transceiver module 410 further includes a plurality of receivers (e.g., optical sensors 708 in FIG. 7) configured to convert the set of optical signals to the set of electrical signals to be transmitted to the one or more rack servers 120 using a plurality of electrical interconnects 304.

In some embodiments, the server rack 100 further includes the one or more rack servers 120 configured to receive the plurality of outgoing signals. The plurality of incoming signals include a set of optical signals received via the plurality of detachable optical interconnects 302, and the plurality of outgoing signals includes a set of electrical signals that are configured to be transmitted to the one or more rack servers 120.

In some embodiments, the server rack 100 further includes the one or more rack servers 120 configured to provide the plurality of incoming signals. The plurality of incoming signals include a set of electrical signals provided by the one or more rack servers 120, and the plurality of outgoing signals includes a set of optical signals transmitted via the plurality of detachable optical interconnects 302.

In some embodiments, the server rack 100 further includes the one or more rack servers 120 configured to receive the plurality of outgoing signals. The plurality of incoming signals include a set of incoming optical signals received via the plurality of detachable optical interconnects 302, and the plurality of outgoing signals includes a set of outgoing optical signals that are configured to be transmitted to the one or more rack servers 120.

In some embodiments, the server rack 100 further includes the one or more rack servers 120 configured to provide the plurality of incoming signals. The plurality of incoming signals include a set of incoming optical signals provided by the one or more rack servers 120, and the plurality of outgoing signals includes a set of output optical signals transmitted via the plurality of detachable optical interconnects 302. Further, in some embodiments, the one or more rack servers 120 include a plurality of GPUs configured to implement machine learning operations.

In some embodiments (FIGS. 9A and 9B), the coolant 506 includes a first coolant 506. The rack structure further includes a server slot 104A configured to receive a first rack server 120A. The cooling structure 510 includes a first cooling structure, and the server slot 104-1 further includes a second cooling structure, which is configured to inject a second coolant and output the second coolant in parallel with the first cooling structure, thereby allowing the second coolant to at least partially carry away the heat generated by the first rack server 120A. The first coolant 506 is split from the second coolant before it enters the inlet 502, and merges with the second coolant after it exits the outlet 504.

In some embodiments, the server rack 100 further includes a coolant pump 908 (FIG. 9A) coupled between the inlet 502 and the outlet 504, and a coolant controller 910 (FIG. 9A) coupled to the coolant pump 908. The coolant controller 910 is configured to control the coolant pump 908 to push the coolant 506 into the inlet 502 of the cooling structure 510 and draw the coolant 506 out of the outlet 504 of the cooling structure 510. Further, in some embodiments, the coolant pump 908 is disposed in a first slot 104-1 of the server rack 100, and the transceiver module 410 is disposed in a second slot 104-2 of the server rack 100 that is distinct from the first slot 104-1.

In some embodiments, the plurality of detachable optical interconnects 302 have a data communication bandwidth greater than 1 Tb/s, and the transceiver module 410 has a power consumption level greater than 25 W.

In some embodiments, the server rack 100 includes, or is coupled to, a plurality of panels configured to convert the server rack 100 to a server cabinet.

In some embodiments, the switch box 110 encloses both the transceiver module 410 and the cooling structure 510.

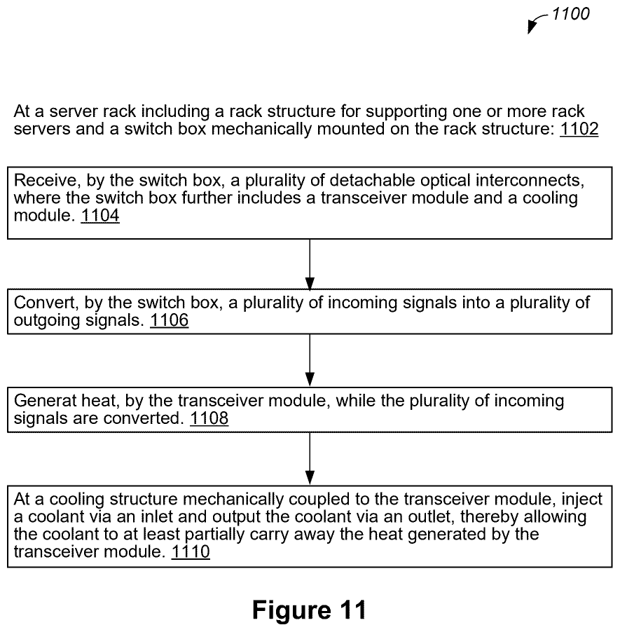

FIG. 11 is a flow diagram of a method 1100 implemented at a server rack 100 (FIG. 1) for managing incoming data, in accordance with some embodiments. The server rack 100 (FIGS. 1A and 1B) includes (operation 1102) a rack structure for supporting one or more rack servers 120, a switch box 110 that is mechanically mounted on the rack structure. The switch box 110 mechanically receives (operation 1104) a plurality of detachable optical interconnects 302, and converts (operation 1106) a plurality of incoming signals 312 to a plurality of outgoing signals 314 (FIGS. 3A and 3B). The switch box 110 further includes a transceiver module 410, and a coolant structure 510 coupled to the transceiver module 410. The transceiver module 410 generates (operation 1108) heat while the plurality of incoming signals 312 are converted. The coolant structure 510 injects (operation 1110) a coolant 506 (FIG. 5B) via an inlet 502 of the cooling structure 510 and outputs the coolant 506 via an outlet 504 of the cooling structure 510, thereby allowing the coolant 506 to at least partially carry away the heat generated by the transceiver module 410.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

What is claimed is:

1. A server rack, comprising:
a rack structure for supporting one or more rack servers;
a switch box mechanically mounted on the rack structure, wherein the switch box is configured to receive a plurality of detachable optical interconnects and further includes:
a transceiver module configured to convert a plurality of incoming signals to a plurality of outgoing signals and generate heat while the plurality of incoming signals are converted; and
a cooling structure coupled to the transceiver module, wherein the cooling structure includes an inlet and an outlet, and is configured to inject a coolant via the inlet and output the coolant via the outlet, thereby allowing the coolant to at least partially carry away the heat generated by the transceiver module.

2. The server rack of claim 1, wherein the cooling structure comprises a metallic plate having a contact surface, and the metallic plate comes into contact with the transceiver module via the contact surface for absorbing the heat generated by the transceiver module.

3. The server rack of claim 2, wherein the metallic plate includes a coolant channel sealed within the metallic plate, and each of the inlet and the outlet is coupled to a respective edge of the metallic plate and connected to a respective end of the coolant channel, the coolant channel extending substantially parallel to the contact surface from the inlet to the outlet.

4. The server rack of claim 1, wherein the switch box further comprises a first set of ports configured to receive a plurality of detachable electrical interconnects, and each of the first set of ports is configured to exchange electrical signals with a respective rack server mounted on the rack structure.

5. The server rack of claim 1, wherein the switch box further comprises a second set of ports configured to receive a plurality of detachable electrical interconnects, and the second set of ports is coupled to a plurality of rack server on a set of one or more alternative server racks, each alternative server rack including at least one rack server electrically coupled to a respective port of the second set of ports.

6. The server rack of claim 1, wherein the transceiver module and the cooling structure are inseparable from one another using manual manipulation without using a tool, the rack structure includes a first slot configured to receive the switch box including the transceiver module and the cooling structure, allowing the switch box to be detached from the server rack and the transceiver module and the cooling structure to be replaced in the switch box.

7. The server rack of claim 1, wherein at least one of the transceiver module and the cooling structure is mechanically fixed on, and inseparable from, the switch box using manual manipulation without using a tool.

8. The server rack of claim 1, wherein the transceiver module includes a plurality of optical engines and a switching application specific integrated circuit (ASIC), the plurality of optical engines configured to exchange optical signals with the plurality of detachable optical interconnects, the switching ASIC configured to exchange electrical signals with the plurality of optical engines.

9. The server rack of claim 1, wherein the transceiver module includes a switching ASIC, and the switch box further includes a plurality of optical engines that are distinct from, and electrically coupled to, the transceiver module.

10. The server rack of claim 9, wherein the switch box is configured to receive the plurality of detachable optical interconnects via a plurality of fiber ports, and each of the plurality of optical engines is detachably coupled to a respective fiber port.

11. The server rack of claim 10, wherein the switching ASIC of the transceiver module is electrically coupled to the plurality of optical engines via an electrical switching cable, and the plurality of optical engines further include a digital signal processing (DSP) block configured to exchange a digital electrical signal with the switching ASIC via the electrical switching cable.

12. The server rack of claim 1, wherein the plurality of outgoing signals include a set of optical signals, and the transceiver module further comprises:
a plurality of laser diodes configured to emit the set of optical signals to be transmitted via the plurality of detachable optical interconnects; and
a plurality of laser driver circuits coupled to the plurality of laser diodes, wherein the plurality of laser driver circuits are configured to receive the plurality of incoming signals and provide electrical signals to drive the laser diodes to generate the set of optical signals.

13. The server rack of claim 1, wherein the plurality of outgoing signals include a set of electrical signals and the plurality of incoming signals include a set of optical signals, and the transceiver module further comprises:
a plurality of receivers configured to convert the set of optical signals to the set of electrical signals to be transmitted to the one or more rack servers using a plurality of electrical interconnects.

14. The server rack of claim 1, further comprising the one or more rack servers configured to receive the plurality of outgoing signals, wherein the plurality of incoming signals include a set of optical signals received via the plurality of detachable optical interconnects, and the plurality of outgoing signals includes a set of electrical or optical signals that are configured to be transmitted to the one or more rack servers.

15. The server rack of claim 1, further comprising the one or more rack servers configured to provide the plurality of incoming signals, wherein the plurality of incoming signals include a set of electrical or optical signals provided by the one or more rack servers, and the plurality of outgoing signals includes a set of optical signals transmitted via the plurality of detachable optical interconnects.

16. The server rack of claim 1, wherein:
the coolant includes a first coolant;
the rack structure further includes a server tray configured to receive a first rack server;
the cooling structure includes a first cooling structure, and the server tray further includes a second cooling structure, which is configured to inject a second coolant and output the second coolant in parallel with the first cooling structure, thereby allowing the second coolant to at least partially carry away the heat generated by the first rack server; and
the first coolant is split from the second coolant before it enters the inlet, and merges with the second coolant after it exits the outlet.

17. The server rack of claim 1, further comprises:
a coolant pump coupled between the inlet and the outlet; and
a coolant controller coupled to the coolant pump, wherein the coolant controller is configured to control the coolant pump to push the coolant into the inlet of the cooling structure and draw the coolant out of the outlet of the cooling structure;
wherein the coolant pump is disposed in a first tray of the server rack, and the transceiver module is disposed in a second tray of the server rack that is distinct from the first tray.

18. The server rack of claim 1, wherein:
the plurality of detachable optical interconnects have a data communication bandwidth greater than 1 Terabits per second (Tb/s), and the transceiver module has a power consumption level greater than 25 W;
the server rack includes, or is coupled to, a plurality of panels configured to convert the server rack to a server cabinet; and
the switch box encloses both the transceiver module and the cooling structure.

19. A modulator device, comprising:
a transceiver module enclosed in a switch box that is configured to receive a plurality of detachable optical interconnects, the transceiver box configured to convert a plurality of incoming signals to a plurality of outgoing signals and generate heat while the plurality of incoming signals are converted; and
a cooling structure coupled to the transceiver module, wherein the cooling structure includes an inlet and an outlet, and is configured to inject a coolant via the inlet and output the coolant via the outlet, thereby allowing the coolant to at least partially carry away the heat generated by the transceiver module.

20. A switch box, comprising:
a transceiver module configured to convert a plurality of incoming signals to a plurality of outgoing signals and generate heat while the plurality of incoming signals are converted; and
a cooling structure coupled to the transceiver module, wherein the cooling structure includes an inlet and an outlet, and is configured to inject a coolant via the inlet and output the coolant via the outlet, thereby allowing the coolant to at least partially carry away the heat generated by the transceiver module;
wherein the switch box is configured to receive a plurality of detachable optical interconnects.
